(19) United States
(12) Patent Application Publication
(10) Pub. No.: US 2015/0303941 A1
(43) Pub. Date: Oct. 22, 2015

(54) METHOD AND SYSTEM FOR PROCESSING TEXT

(71) Applicant: Kieran HAYES, (US)

(72) Inventor: Kieran HAYES, Oxfordshire (GB)

(21) Appl. No.: 14/436,045

(22) PCT Filed: Oct. 15, 2013
(86) PCT No.: PCT/GB2013/052686

§ 371 Date: Apr. 15, 2015

(30) Foreign Application Priority Data
Oct. 15, 2012 (GB) 1218474.3

(51) Int. Cl. H03M 7/30; G06F 17/22; G06F 17/21

(52) U.S. Cl. CPC H03M 7/70; G06F 17/21; G06F 17/2205

(57) ABSTRACT

A computer-implemented method at an electronic device, the method comprising: receiving plain text from one of the plurality of software applications; processing the text into compressed text, while maintaining comprehensibility of the compressed text; and returning the compressed text to the one of the plurality of software application.

### FIELD OF THE TECHNOLOGY

The present disclosure relates to electronic devices, methods of operation thereof, and computer software for facilitating a text processing system, particularly for shortening text.

### BACKGROUND

In text-based forms of communication, particularly in forms where character limits are imposed, there is a need to convey a comprehensible message using the fewest characters possible. For example, as the size of an SMS message is limited to 160 characters, users struggle to keep within such limits using traditional English, and so turn to ways of keeping their messages below this limit. The popularisation and mainstream appeal of SMS messages in the last few decades has led to an almost universally understood set of abbreviations and slang for shortening text, known as text-speak (also referred to as textese, txtspk, chat speak, and SMS language, for example).

Over time, text-speak has developed so that fewer text characters are required to portray the same information as if using traditional language. This can be achieved through a number of mechanisms, such as: by removing characters from words while still allowing the original meaning to be apparent (for example, shortening ‘tomorrow’ to ‘tmrw’, and ‘I'm’ to ‘lm’); replacing groups of letters with characters that have the same phonetic sounds (for example, ‘you’ to ‘u’, and ‘before’ to ‘b4’); using pre-established acronyms (for example, ‘be right back’ to ‘brb’); replacing individual words with pictograms (for example, ‘love’ to the pictogram of a heart, ‘<3’); and conveying emotions and feelings with pictograms (for example, conveying laughter with ‘xD’).

While text-speak can be advantageous in its ability to reduce message length and data usage, there are disadvantages that arise from using it. One disadvantage is that although text-speak can be intuitive to read, in order to write it one needs prior knowledge of accepted rules and acronyms. This introduces a learning curve that could discourage new users from enjoying the benefits of text-speak, and, if learned incorrectly, may introduce confusion. Another disadvantage is that although the resulting text may involve fewer characters, the actions required by a user to write text-speak may be more numerous and cumbersome. For example, ‘l8r’ is the text-speak version of ‘later’, and although it uses fewer characters, it can be more cumbersome for users to type, particularly on mobile phone keyboards where a user has to switch to ‘numeric’ mode to type the ‘8’ and then switch back to the alphabetic keyboard to finish the word. Although text-speak is designed to be as intuitive as possible, there are still abbreviations, words and symbols that require prior knowledge to understand, and therefore a user of text-speak would be unable to use it to communicate with someone who has never used it.

As text-speak is often used when communicating on mobile devices, text processing systems implementing text-speak would have to be designed to work efficiently without overexerting a device and draining power.

Therefore, there is a need for an efficient, intuitive text-processing system that facilitates communication using fewer characters than traditional languages.

### BRIEF DESCRIPTION OF DRAWINGS

Examples of the present proposed approach will now be described in detail with reference to the accompanying drawings, in which:

FIG. 1 is a block diagram illustrating an electronic device in accordance with example embodiments of the present disclosure in accordance an example embodiment of the present disclosure;

FIG. 2a is a system diagram illustrating the text processing system as an API interacting with example processes in accordance an example embodiment of the present disclosure;

FIG. 2b is a system diagram illustrating an application incorporating the text processing system as an internal function in accordance an example embodiment of the present disclosure;

FIG. 2c is a system diagram illustrating a system architecture for implementing a text processing system in accordance an example embodiment of the present disclosure;

FIG. 3 is a flow diagram illustrating the initial start-up steps of a text processing system in accordance an example embodiment of the present disclosure;

FIG. 4 is a flow diagram illustrating the initial steps of a text processing engine in accordance an example embodiment of the present disclosure;

FIG. 5 is a flow diagram illustrating the steps taken for processing text with phrases in accordance an example embodiment of the present disclosure;

FIG. 6 is a flow diagram illustrating the steps for loading exclusion data into memory in accordance an example embodiment of the present disclosure;

FIG. 7 is a flow diagram illustrating the steps of processing input plant text into blocks and the subsequent processing of the blocks in accordance an example embodiment of the present disclosure;

FIG. 8 is a flow diagram illustrating the steps for processing punctuation in a block of text in accordance an example embodiment of the present disclosure;

FIG. 9 is a flow diagram illustrating the steps for shortening text in accordance an example embodiment of the present disclosure; and,

FIG. 10 is a flow diagram illustrating the steps performed on excluded blocks of text in accordance with an example embodiment of the present disclosure;

### DETAILED DESCRIPTION

In one embodiment, the present disclosure provides a computer program on an electronic device for processing text, the computer program running as a background service in communication with a plurality of communication applications on the electronic device, and performing the method of: receiving plain text from one of the plurality of software applications; processing the text into compressed text, while maintaining comprehensibility of the compressed text; and, returning the compressed text to the one of the plurality of software applications.

This embodiment provides a way for a single computer program to provide a text processing service to multiple applications on a device, and automatically shortening received text into comprehensible, compressed text back to the application that sent the text. By automatically converting plain text to comprehensible, compressed text, a user writing the message does not have to have any prior knowledge of what rules to use in order to reduce the character length of plain text in a way that maintains comprehensibility, thereby reducing the mental burden on the user. This automatic process may also save time for the user, as they would not have to perform cumbersome user interactions to insert symbols and numbers that may be required for compressing text, as the whole text submitted to the computer program would be automatically converted. Automatically compressing text can also reduce the bandwidth requirements of an electronic device if the text is intended for transmitting to another device, and thus reduces system resources used and may result in cheaper carrier charges to a user.

In some example embodiments, the compressed text is text-speak. By using a universally understood compression system such as text-speak, it is more likely that a compressed message will be comprehensible, as text-speak is a commonly understood text-shortening language and is relatively intuitive to understand even to those with limited prior knowledge of the language.

In some example embodiments, the step of processing the text into compressed text includes accessing a dictionary comprising one or more mappings of groups of text characters to compressed text. By accessing a dictionary or data store to process text, efficient methods of data-lookup can be employed in order to quickly and efficiently perform the compression.

In some example embodiments, the dictionary is stored locally on the electronic device. By storing the dictionary locally on the electronic device, the bandwidth usage of the device is reduced and the system may even be used with limited or no connectivity.

In some example embodiments, the dictionary further comprises custom mappings added by the electronic device. By allowing custom mapping to be added to the dictionary, the text processing system allows a user to automatically convert their own shortening rules for words not already in the dictionary or for words that the user has discovered a more efficient shortening for.

In some example embodiments, the processing the text into compressed text is ceased when the compressed text falls below a predetermined size. Text compression may be used to bring input text below a certain threshold, for example the SMS message limit of 160 characters. Therefore, once a compressed text has fallen below a certain threshold, the system may stop compressing, as the goal of the compression has been achieved and there is no more need to use further system resources.

In some example embodiments, the predetermined size is the string length. By setting the predetermined size to be a specific string length, the text compression may be limited to reducing to specific character lengths, such as the limits enforced by SMS messages and Twitter® messages.

In some example embodiments, the processing of text comprises: splitting the received text into blocks of text, said splitting determined by the positions of space characters in the received text; and, for each block of text, if it the block of text is determined to have a mapping in the dictionary, replacing it with the corresponding compressed text. Splitting the text into blocks can simplify the processing of the text as it provides discrete, relatively small strings that can be operated on at a time.

In some example embodiments, the processing of text further comprises: for each block of text, if the block of text is determined to be an excluded block of text, skipping the step of determining if the block of text has a mapping in the dictionary. By skipping excluded blocks of text, the processing system can reduce processor usage of trying to locate a suitable compressed text.

In some example embodiments, the compressed text uses less memory than the received text. The compression mapping employed may be used to reduce the memory usage of text, thereby reducing data usage of storing or transferring text.

In some example embodiments, the method further comprising: detecting that the received text is compressed text and processing the text into uncompressed text. By determining that received text is compressed text and processing the text into uncompressed text, the proposed embodiment provides a way of converting the text into the original input text. Doing so may be beneficial to users who are not familiar with the compressed language being used, such as text-speak.

In some example embodiments, the plurality of communication applications include one or more of: a text messaging application, a Twitter® application, an email application, and a social networking application.

In another embodiment, the present disclosure provides an electronic device comprising: one or more processors; and, memory comprising instructions for a computer program, the computer program running as a background service in communication with a plurality of communication applications on the electronic device, wherein when said instructions are executed by one or more of the processors, cause the computer program in the electronic device to: receive plain text from one of the plurality of software applications; process the text into compressed text, while maintaining comprehensibility of the compressed text; and, return the compressed text to the one of the plurality of software applications.

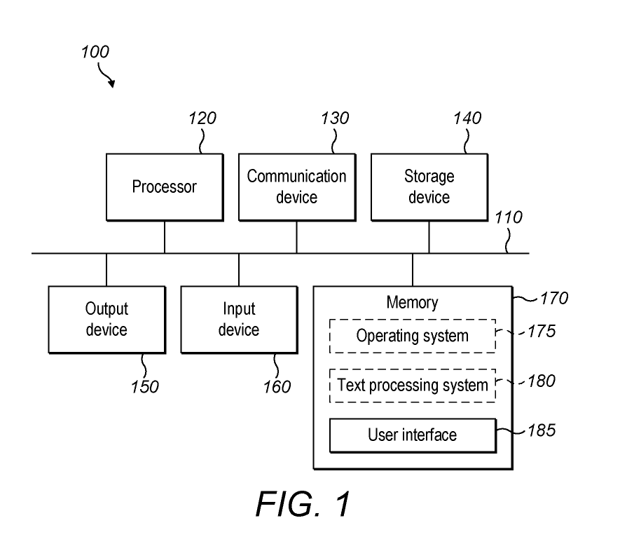

The proposed text processing system may be implemented using the computer system 100 of FIG. 1. FIG. 1 is provided as an example for the purposes of explaining the invention and one skilled in the art would be aware that the components of such a system may differ depending on requirements and user preference. The computer system of FIG. 1 comprises one or more processors 120 connected to a system bus 110. Also connected to the system bus 110 is working memory 170, which may comprise any random access or read only memory (RAM/ROM), output device 150 and input device 160. A user may interact with a user interface using input device 160, which may comprise, amongst others known in the art, a mouse, pointer, keyboard, a microphone or touch-screen. If a touch-screen is used, output device 150 and input device 160 may comprise a single input/output device. The output device 150 could also be a speaker. The computer system may also optionally comprise one or more storage devices 140 and communication device 130, which may enable communication over a network (non-shown). Storage devices 140 may be any known local or remote storage system using any form of known storage media.

In use, computer program code is loaded into working memory 170 to be processed by the one or more processors 120. In the example of FIG. 1, an operating system (OS) 175 is optionally loaded into memory 170 together with optional computer-program code for implementing a text processing system 180. The data category defined using the present invention may be used within text processing system 180 or by other applications. Working memory 170 also comprises computer-program code 185 for implementing a user interface. The system may be implemented using library components. The OS 175 and/or the computer-program code 180 and 185 may comprise suitably configured computer program code to enable the proper functioning of the computer system as described above.

It is important to note that while the present invention has been described in a context of a fully functioning data processing system, those of ordinary skill in the art will appreciate that the processes of the proposed system are capable of being distributed in the form of a computer readable medium of instructions and a variety of forms and that the present invention applies regardless of a particular type of signal bearing media actually used to carry out distribution. Examples of computer readable media include recordable-type media such as floppy disks, a hard disk drive, RAM, DVDs and CD-ROMs as well as transmission-type media such as digital and analogue communications links.

Generally, any of the functionality described in the text or illustrated in the figures of the application can be implemented using software, firmware (e.g., fixed logic circuitry), programmable or nonprogrammable hardware, or a combination of these implementations. The terms “component” or “function”, as used herein, generally represents software, firmware, hardware or a combination of these. For instance, in the case of a software implementation, the terms “component” or “function” may refer to program code that performs specified tasks when executed on a processing device or devices. The program code may be stored in one or more computer readable memory devices as described above. The illustrated separation of components and functions into distinct units may reflect an actual physical grouping and allocation of such software and/or hardware, or can correspond to a conceptual allocation of different tasks performed by a single software program and/or hardware unit.

The computer system 100 may be any electronic device capable of performing operations in accordance with machine code. In one example embodiment, the computer system 100 is a personal computer providing the text processing system 180 to the user of the personal computer. In another example embodiment, the computer system 100 is a server machine or device connected to a user equipment to provide the text processing system 180 to the user of equipment via a communication channel. In yet another example embodiment, the computer system 100 is a communication device and, more particularly, is a mobile communication device, such as a phone, a smartphone or a speech device, having data and voice communication capabilities, and the capability to communicate with other computer systems or users; for example, via the Internet. Other example computer systems 100 may include tablet computers, wearable device, multi-processor systems, multi-server systems, set-top boxes, and mainframes.

While the computer system 100 of FIG. 1 shows a single electronic device, elements of this device may be spread across multiple devices. For example, the text processing system 180 may be located in a cloud, distributed, or internet-based environment, and the user-related tasks are performed by separate remote devices. The data stored in the storage device 140 or memory 170 may be stored remotely and linked via an appropriate topology, such as a Local Area Network (LAN) or Wide Area Network (WAN), or the internet itself.

The proposed text processing system may be encapsulated into a bespoke computer device or data processor, the device being specifically programmed, configured and built to perform any of the computer executable instructions disclosed herein.

The proposed text processing system may, for example, be encapsulated into a script, or compiled as a just-in-time compiled, or true compiled machine code, or assembly code. Elements of the system may be stored, distributed, or executed from any conceivable computer media, for example optical storage, solid state storage, and pre-programmed microchip or silicon chip storage such as EPROM.

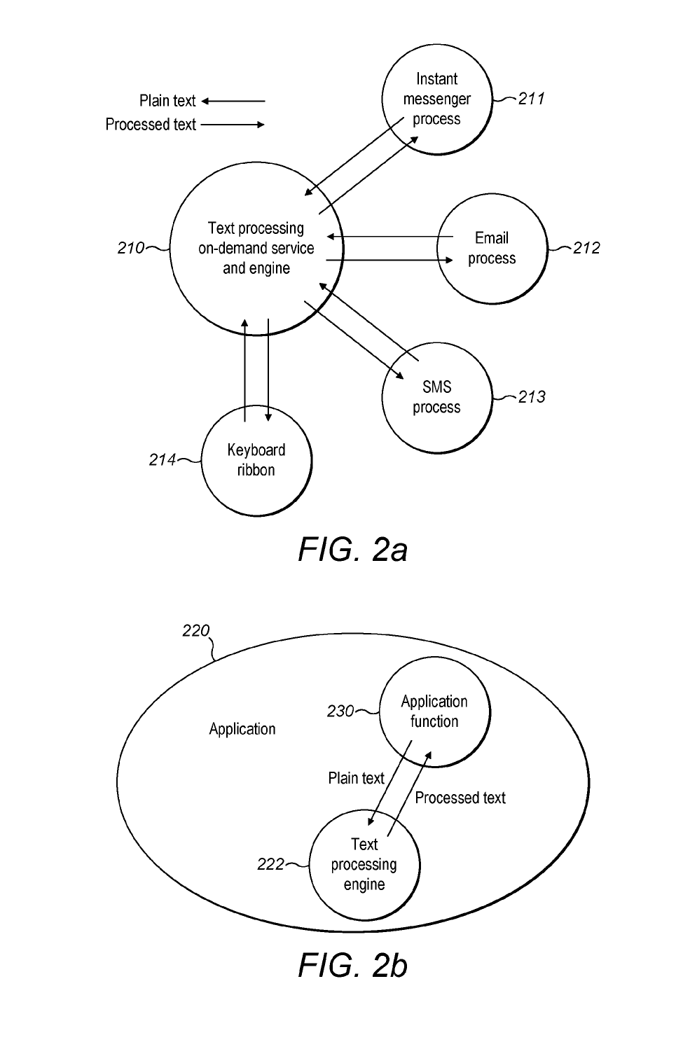

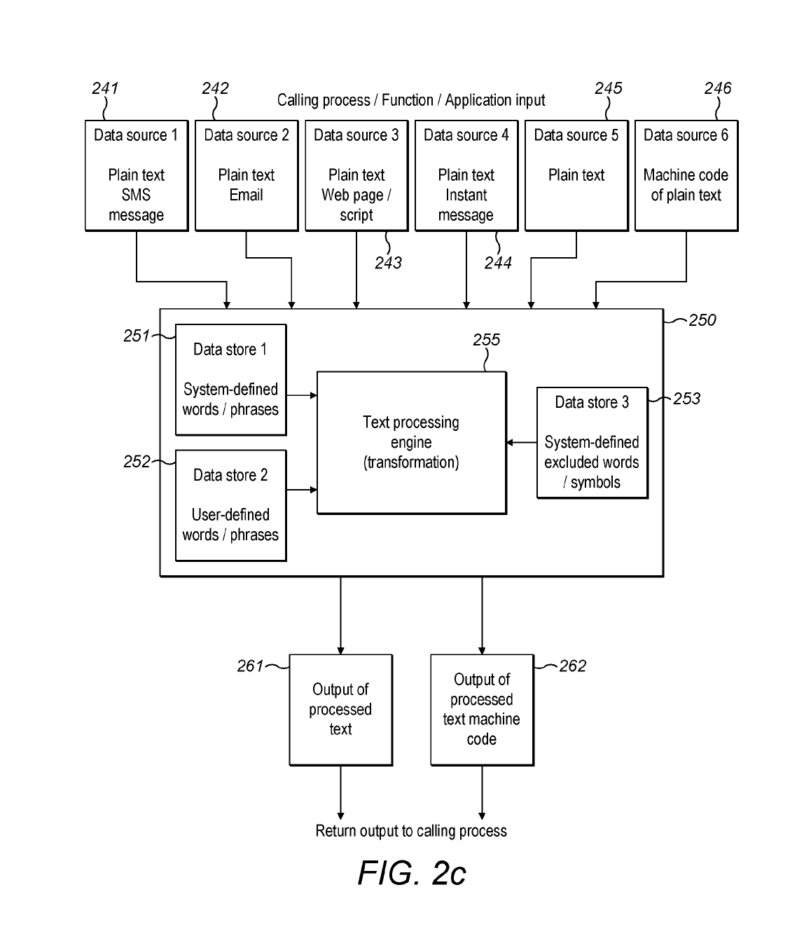

Reference will now be made to FIG. 2a, which is a system diagram illustrating a preferred embodiment, where the text processing system is provided as an on-demand ‘service’ 210 on a host computer or device. The text processing on-demand service and engine 210 may be a service on an electronic device other than the device utilising the service. The text processing service may be accessed by other processes by making calls to an application programming interface (API) of the proposed system which is accessible via a service. Such other processes may include, for example, an instant messenger (IM) process 211, an email process 212, an SMS process 213, and a keyboard ribbon 214.

Providing the text processing system as a service, may be advantageous over a dedicated application as it allows multiple applications on a device to be able to access the service. As a result, any third party applications installed on the device need only have limited or no modifications to be able to use the text processing system. Furthermore, by having the text processing system as a separate system to the applications using it, the system can be modified and updated when required and is not dependent on the update cycles of other applications. Using an API may reduce the complexity of incorporating the proposed text processing system into a device, as any third party applications would simply have to use a function call or a remote method invocation of the API, providing the input of plain text and receive compressed text. Providing the service as a background service allows the system to be available for function calls whenever a third party requires access to the service, without having to wait for the initial start-up of the service.

An application may be constructed to intercept incoming data from other applications on the device, consolidating the incoming data to be processed by the API into a single application listing the incoming data that was deemed to be acted upon by the API. This application may subsequently forward the data to the API and act accordingly.

FIG. 2b illustrates another example embodiment of the proposed text processing system, where the system is included within a computer software application 220, such as a PC program or mobile app. In this example embodiment, the text processing engine 222 may be accessed by an application function 230 that makes a call to a text processing API, providing plain text as input and receiving processed, compressed text in return. The third party application 220 may implement the text processing engine 222 in a customised way, by removing steps or adding its own steps appropriate for the application.

FIG. 2c is a system diagram illustrating the system architecture of an example embodiment of the proposed text processing system. The text processing system 250 may receive text for processing through a number of data sources. For example, the system 250 may receive plain text from an SMS message 241, an email 242, a web page or script 243, an instant message 244, a general text source 245 or the machine code representing a plain text input 246. These data sources may be on the same device as the text processing system or may be on an external user device.

The text processing engine 255 may have access to one or more data stores to facilitate the processing of text. A first data store 251 may contain common words and phrases and their associated shortened forms. The data store 251 may be located on the same device as the processing engine 255 or more be located remotely. The text processing system 250 may be equipped with the ability to update the words and phrases from an external source, such as memory stick, flat file or the internet, either automatically or as a result of a user trigger.

Another data store may contain words and phrases that the processing system 250 can remove from a plain text without changing the meaning of a sentence within the plain text. Such words may include ‘a’ or ‘the’, which in certain scenarios may be omitted without detracting from the intended meaning of the input text. The system 250 may provide the user with the choice to include the removal of these symbols or not as a preference or option to be set prior to execution of the processing. This data may be included in the first data store 251 as a mapping from pre-defined words to blanks instead of a separate data store.

Data store 2 252 may also be included to define user-defined words and phrases and their associated user-define compressed versions. Such a user-defined data store may be useful when there are certain words and phrases (such as names and places) that a user has determined their own shortened forms for.

Data store 3 253 may contains a list of words, phrases and symbols that are determined to be uncompressible, and therefore excluded from the compression process. For example, the word “is” may not be considered compressible as there is no shortened version of “is” that retains its meaning in the plain text. The commonly used smiley “ [symbol] ” character may also be contained in such as data store 253 as no shortened version of their representation can be achieved. The system 250 could then provide the user with the choice to include the removal of these symbols or not as a preference or option set prior to execution of the compression or by a parameter sent to the system 250. When the text transformation function 255 takes place, these system words, phrases and symbols defined in this list of excluded entries 253 are ignored and are not analysed when the engine 255 attempts to compress plain text.

Some or all of these data stores may be synchronised with and assigned to other users. For example, data store 2 252 which includes the user-defined words and phrases may also be accessible to another user so that a user-defined compressed word sent by one user can be uncompressed by the device of the receiving user. The data store synchronised with another user may be configured such that the compressed text is unreadable to any user that does not have a synchronised data store. In this way, a level of security can be added to the text being sent, as the receiving device can only render the received text as readable by the receiving user by processing the API call using the synchronised user dictionary.

The text processing engine 255 carries out the transformation from plain text to compressed text and does so by utilising the data sources, data stores and the instructions defined by the text processing system 250.

Once text has been processed and compressed, it may be output either as processed text 261 or machine code for the processed text 262, or both may be provided as outputs. In a preferred embodiment, when input plain text is provided, processed text 261 is output, and when the machine code of plain text 246 is provided, the machine code of processed text 262 is output by the system 250. The output of the system 250 may be provided to whatever process, application or service made the initial call to the text processing function.

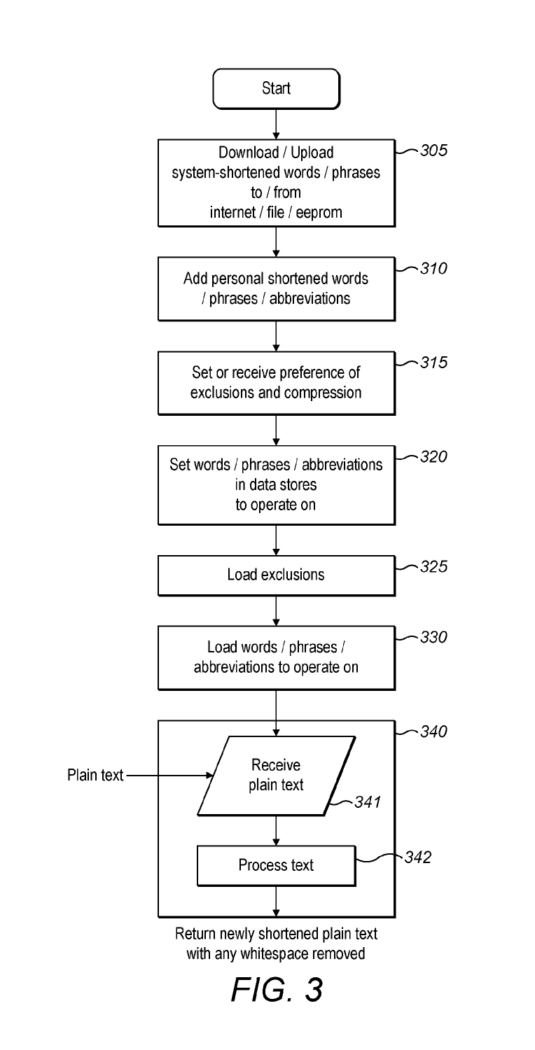

FIG. 3 illustrates the initial start-up steps of an example embodiment of the proposed system. At step 305 the system populates data store 1 251 containing the system-define words and their associated shortened forms. The data store may be populated by downloading (or being uploaded) the data store entries from a source location, for example a local file, the EEPROM, or from an external file located on the internet. At step 310, the system adds any user-defined, personal entries to the data store containing user-defined shortenings. These user-defined mappings may be stored in a separate data store (for example data store 2 252) or in the same data store as other mappings in the system. At step 315, preferences for the system may be set. There are a number of preferences that may define how the system behaves, for example how much should the system aim to shorten the text by, or whether it should allow user-defined entries or entries defined in an exclusion data store 253. Each given preference may be defined prior to execution of the system as a stored preference, or may be passed to the system as a parameter on execution and set by a user input or a third party application. For example, there may be a preference that once an input text has been shortened to below 160 characters for an SMS message, the processing system should stop shortening the text. Such a preference may be automatically invoked if the input text is determined to come from an SMS process.

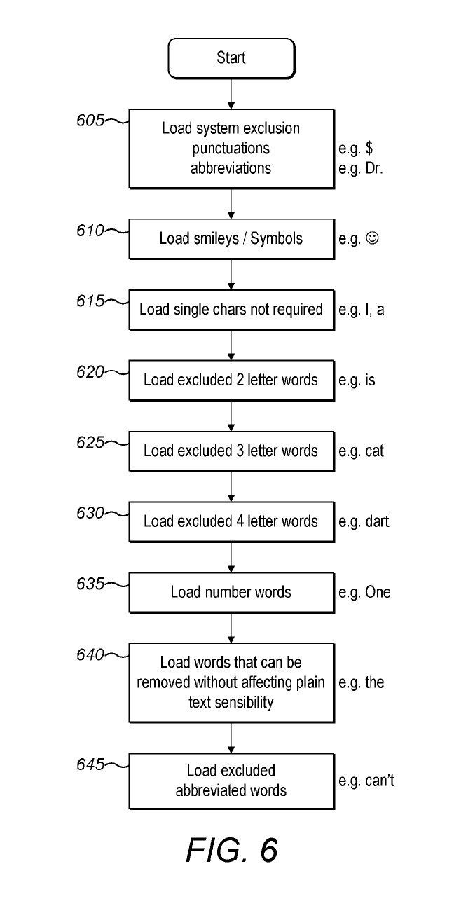

On receiving the preferences, the system may then set which entries in the data stores to operate on 320. This may involve compiling a single list of all entries that can be shortened by consolidating the data stores based on system preferences. At step 325, the system loads any excluded entries and is described in further detail in the description of FIG. 6. At step 330, the system loads all the words, phrases and abbreviations that are to be operated on.

Once these initial start-up steps have been performed, the system is ready to receive text 341 into the main text processing engine 340. On receiving the plain text 341, the text is processed 342 to return a newly shortened plain text where, optionally, any whitespaces have been removed. The text processing engine 340 may remain idle and in the background once the initial start-up steps have been performed, and may only start running on receipt of a plain text input. Alternatively, the start-up steps and subsequent text processing may all be triggered by the receipt of a plain text input or a function call to the text processor.

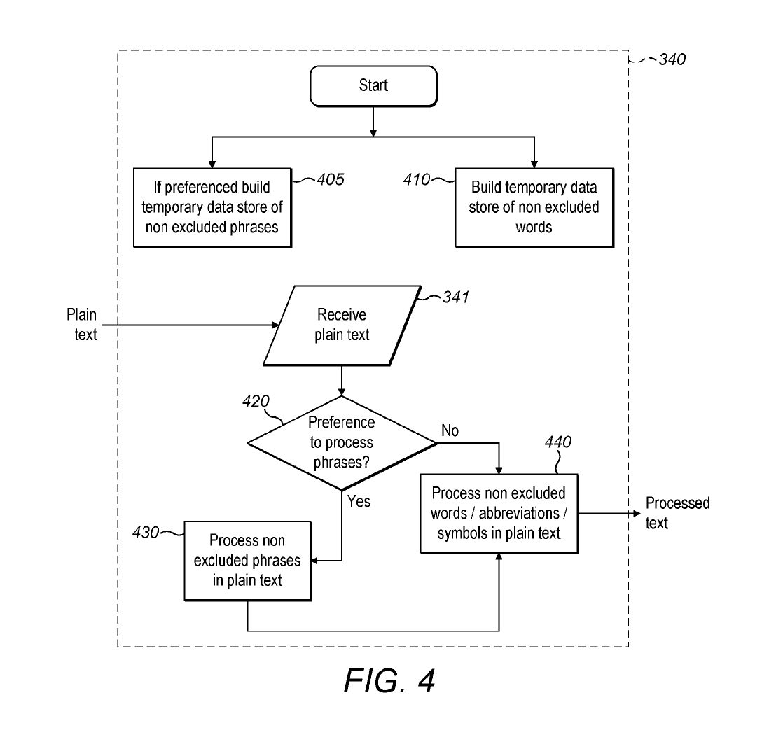

FIG. 4 illustrates the steps of an example text processing engine 340 in more detail. The text processing engine 340 may initialise the moment the main start-up steps of FIG. 3 are completed, or may wait until triggered by the receipt of a plain text input. On initialisation, the engine 340 may build a temporary data store of non-excluded phrases. Such a temporary data store may, for example, be loaded into random access memory for faster access, or may be compiled, optimised and consolidated for quick access and lookup. There may be a preference setting whether such a temporary data store should be built. Similarly, another initialisation step may involve building a temporary data store of non-excluded words 410 for quick access. In an example embodiment, the temporary data store for non-excluded phrases and non-excluded words are the same temporary data store.

Although many of the possible compressions involve taking a word and shortening it, some of the defined compressions may involve taking multiple words or phrases (such as ‘got to go’) and converting them to a single shortened word (for example ‘g2g’). If such mapping from phrases to shortened forms exist, it may be advantageous to compress phrases first before individual words, as compressing phrases may reduce the text length more than compressing individual words, thereby having a greater effect with fewer resources. Therefore, in the example embodiment illustrated, there are two separate processes for processing non-excluded phrases 430 and processing individual words 440. In this example embodiment, there is a preference that determines whether phrases should be considered at all, and if the preference is set to process phrases 420 then the text is first sent to the phrase processor 430 before the output of it is sent to the individual word processor 440. The final output of the individual word processor 440 is the fully processed and compressed text.

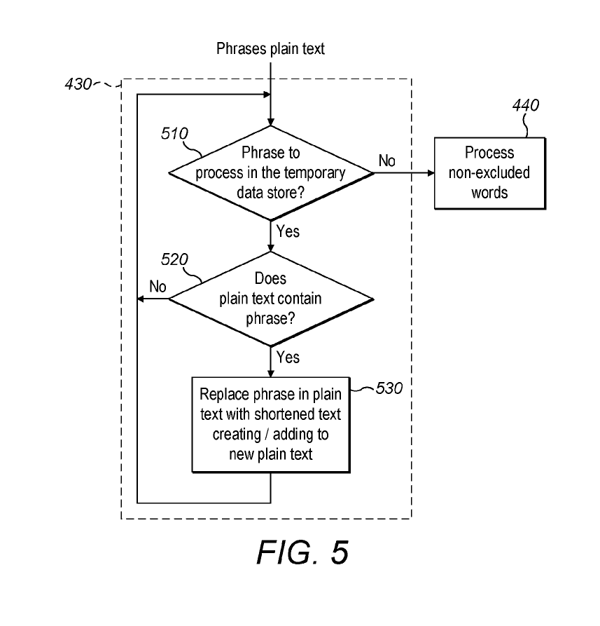

FIG. 5 shows the steps of an example phrase processing function 430. On receiving a plain text input which may contain phrases eligible for compressing, the phrase processing function 430 accesses a data store of phrases 510. This data store may be the temporary data store built in step 405 of FIG. 4, or may be the data store of system-defined mapping 251 where only phrase entries are considered. In an embodiment where a temporary data store has been built for phrases, the function 430 checks 510 if there are any phrase entries in the temporary data store. If there is, then it selects one of the phrases in the temporary data store and checks if the plain text input contains this phrase 520. If the plain text does contain the phrase then at step 530 the function 430 replaces the phrase with the shortened form and removes the entry from the temporary data store as the phrase has now been checked. If the phrase is not found in the plain text, then it is removed from the temporary data store (as it has been checked) and the function returns to step 510, where it checks if there are any entries left in the temporary data store. The function 430 continues this loop until all the phrases in the temporary data store has been checked. At this point, there will be no more phrases in the temporary data store, and so the function 430 will be complete and sends the processed text to the word processing function 440. An alternative to removing checked phrases from a temporary data store is to simply flag a phrase as checked, or to iterate through the store until the end of the temporary data store is reached. This alternative may be advantageous, particularly when a non-temporary data store 251 is accessed, as it preserves the data in the data store.

FIG. 6 shows the exclusion loading step 325 of FIG. 3 in greater detail. Here the system sets up the storage of the system and user defined exclusions into categorised data stores, for example, for smileys, characters, words. The data stores will typically be of a type, in this implementation a string, to store text values for comparison to block items. The contents and classification of the items in an excluded store are not limited to those detailed in FIG. 6, and are only provided as examples.

At step 605, the system loads any punctuation and abbreviations that are defined as excluded, for example the ‘$’ sign and ‘Dr’. At step 610, smileys and symbols (e.g. 0) are loaded, followed by single characters that are not required 615 (e.g. ‘I’ and ‘a’), excluded two letter words 620 (e.g. ‘is’), excluded three letter words 625 (e.g. cat), and excluded four letter fours 630 (e.g. ‘dart’). The system may then load number words 635 (e.g. ‘One’), words that can be removed without affecting the plain text sensibility 640 (e.g. ‘the’), and any excluded abbreviated words 645 (e.g. ‘can't’).

As these entries are loaded into the system, the following pseudo-code may be used:

```
FOR EACH ITEM IN THE DATA STORE
    RETRIEVE THE ITEM FROM THE DATA STORE
    PLACE THE ITEM IN LINEAR STRUCTRE IN
    MEMORY STORAGE.
END FOR EACH.
```

A linear structure is typically an array or hash, but other derivatives and variation exists at varying levels of type and complexity. The linear structure permits the storage of values, for example the letter ‘a’, or the number ‘5’. Items are added, replaced or recalled. Each item in the structure typically has an index and the structure is typically iterated over, locating values, for example by index, by incrementing or decrementing the value of the index of the storage. As an example, words and their shortened text or character representation is stored in this type of storage.

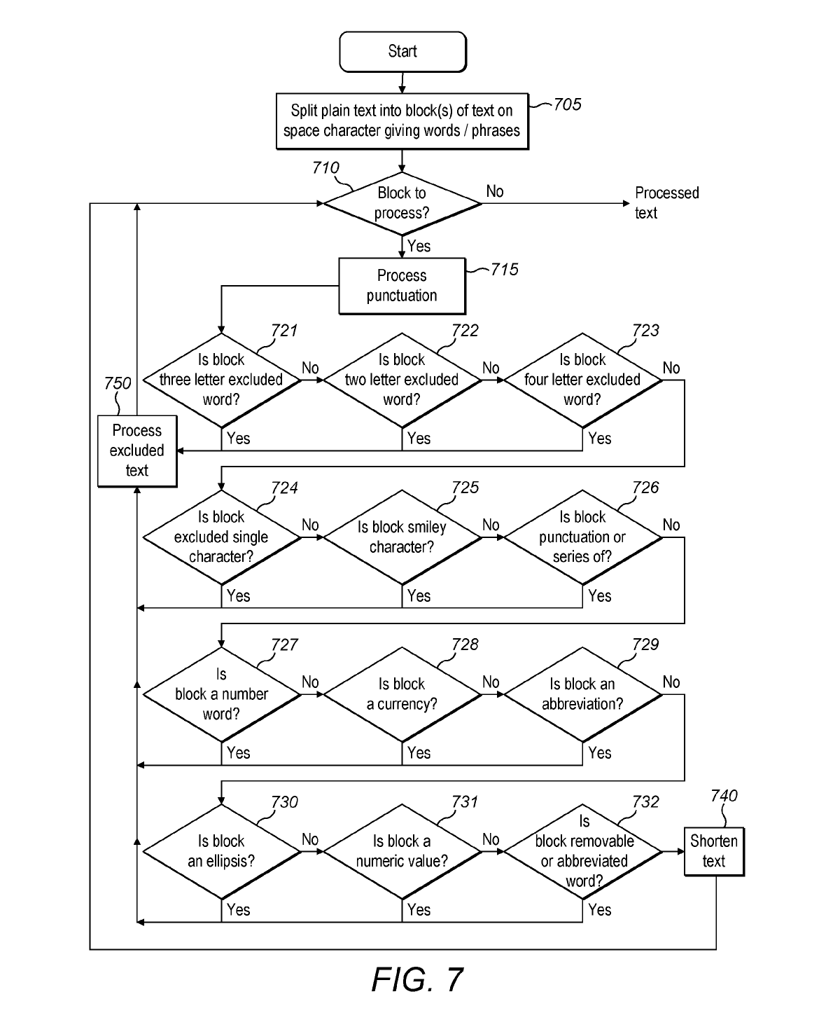

FIG. 7 illustrates the steps taken for processing input plain text by using a block processing system, where a plain text input is split into discrete blocks.

While the proposed system could use a simple find and replace approach for words in the input text, as done in the phrase replacement detailed in FIG. 5, there are disadvantages associated with such a method. Such an implementation would not exhibit the same kind of control over punctuation in the plain text as the block method that will be herewith disclosed. This is because, on execution, the replace function of a common software framework will replace all instances of a character specified at all points in a plain text. For example, if an operation was setup to find and replace ‘.’ (full stops) when executed, the operation would remove all ‘.’ (full stops) in the plain text. However, such behaviour may not be preferable in certain scenarios. For example, a text block “100.00” would become “10000”, which is not the desired result and destroys intelligibility and readability of the plain text.

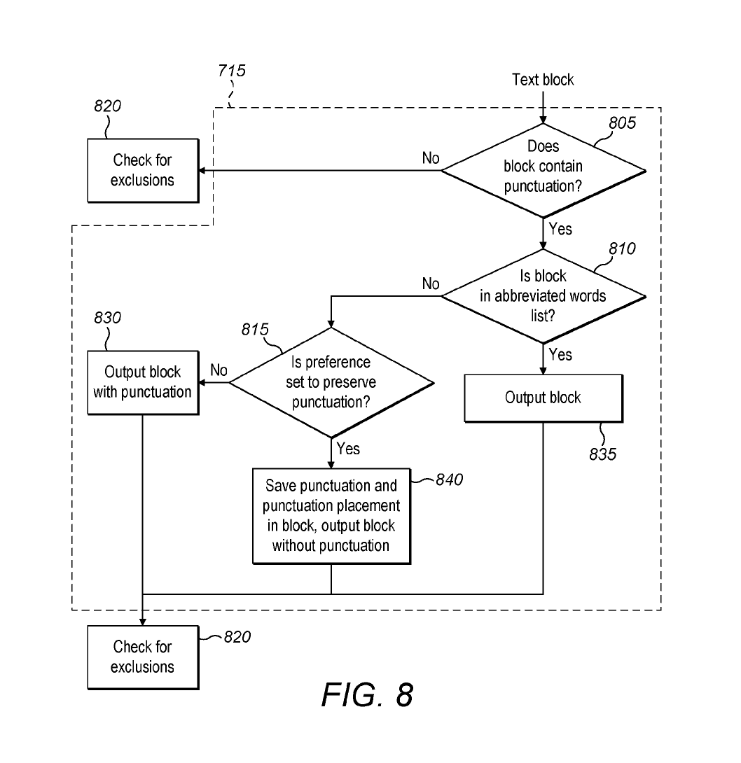

At step 705 of FIG. 7, on receiving a plain text input, the system splits it into discrete blocks, performing the split at the space characters between words, resulting in blocks of individual words. These blocks of words are stored in a temporary data store and are individually processed. At step 710, the system checks if there are any blocks remaining in this temporary data store, and if so, processes the punctuation at step 715. This punctuation processing step will be described in greater detail in the discussion of FIG. 8.

Once the punctuation has been processed, the system checks if the block satisfies any of the exclusion criteria. It does so by passing the block through each of the checks 721 to 732, where the system determines if the block matches any of the exclusions defined in these checks. In this example, the system first checks if the block is one of the three letter word exclusions 721, then the two letter word exclusions 722, followed by the four letter word exclusions, and then the single character exclusion 724, block smiley character exclusion 725, punctuation (or series of) exclusion 726, number word exclusion 727, currency exclusion 728, abbreviation exclusion 729, ellipsis exclusion 730, numeric value exclusion 731, or the removable or abbreviated word exclusion 732. If the block is determined to match any of these pre-defined exclusions, it is sent to the excluded text processing function 750. If the block is not one of the excluded words, then it is sent to the text shortening function 740.

The order in which the exclusion checks are performed may be changed, however, there are advantages to having certain exclusions checked before others. The efficiency of the system can be improved by taking into account common laws of quantitative linguistic (QL) in order to set the ordering of these exclusions.

Current commonly accepted QL laws demonstrate that the most optimal approach is to locate exclusion candidate text blocks based on shorter word lengths, which the proposed embodiment broadly follows. It has also been demonstrated that the most common word length is three, followed by two, then four. Therefore, the proposed system orders the exclusion checks such that three letter words are checked first followed by two letters and then four letters. This should have the effect of improving the efficiency of these exclusion checks, as statistically this lessens the time that the system requires to find and match a potential exclusion block when comparing. Other implementations are envisioned using different orders, for example, where the words are processed by word length one first, then four, two, and three.

Once a block has been processed, either in the excluded text function 750 or the text shortening function 740, it is removed from the list of blocks at step 710 and held ready to output once all the blocks have been processed. Once all the blocks have been processed, the blocks are combined together in order and output as processed text to the original requestor of the compression.

An example of pseudo code that may be used to express the functions of FIG. 7 is:

```
PASS IN THE PLAIN TEXT AS A PARAMETER
SPLIT PLAIN TEXT ON THE SPACE CHARACTER INTO
ITEMS IN LINEAR STORAGE [BLOCK(S)]
WHILE [BLOCKS] HAS ITEMS TO PROCESS
  PROCESSPUNCTUATION
  (IF ITEM IS WITHIN THREE LETTER EXCLUSION DATA STORE)
  OR
  (IF ITEM IS WITHIN TWO LETTER EXCLUSION DATA STORE)
  OR
  (IF ITEM IS WITHIN FOUR LETTER EXCLUSION DATA STORE)
  OR
  (IF ITEM IS WITHIN EXCLUDED SINGLE CHARACTER
  EXCLUSION DATA STORE)
  OR
  (IF ITEM IS WITHIN SMILEY EXCLUSION DATA STORE)
  OR
  (IF ITEM IS PUNCTUATION OR A SERIES OF
  PUNCTUATION CHARACTERS)
  OR
  (IF ITEM IS WITHIN NUMBER WORD EXCLUSION DATA STORE)
  OR
  (IF ITEM IS A CURRENCY)
OR
  (IF ITEM IS AN ABBREVIATION)
  OR
  (IF ITEM IS AN ELIPSE)
  OR
  (IF ITEM IS A NUMERIC VALUE)
  OR
  (IF ITEM IS WITHIN REMOVABLE EXCLUSION DATA STORE)
  OR
  (IF ITEM IS WITHIN ABBREVIATED WORD EXCLUSION
  DATA STORE)
  PROCESS EXCLUDED TEXT
  ELSE SHORTEN TEXT
END WHILE (BLOCKS HAS ITEMS TO PROCESS)
REMOVE ANY REMIANING WHITE SPACE AT THE
END OF THE NEWLY CREATED PLAIN TEXT.
RETURN THE NEWLY CREATED PLAIN TEXT
TO THE CALLING METHOD / FUNCTION /
REQUESTOR.
```

FIG. 8 illustrates the steps performed in an example punctuation processing function 715. On receipt of a text block, if it is detected that the block does not contain any punctuation 805, it is sent on straight to the steps of checking for exclusions 820 (steps 721 to 732 of FIG. 7). If punctuation is detected in the block 805, then the block is moved to step 810 where the system determines if the block matches an entry in an abbreviated word list, and if so, outputs the block 835 and moves it on to check for exclusions 820. The abbreviated words list provides a way for certain abbreviated words to be excluded from punctuation processing, as some words, like ‘we're’, would have its meaning altered if the punctuation is interfered with. If the block does not match any of the words in the abbreviated words list, the block is moved to step 815. Here the system checks whether a preference has been set to preserve punctuation or not. If a preference has been set to preserve punctuation, then the system simply outputs the block with punctuation 830 and proceeds to the exclusion checks 820. However, if a punctuation preservation preference has not been set, then the system saves the punctuation and its position within the block, and outputs the block without punctuation. From here the block continues to be checked for exclusions 820.

An example of pseudo code that can be used to express the functions of FIG. 8 is:

```
(IF ITEM CONTAINS PUNCTUATION)
  (IF ITEM IS IN ABBREVIATED WORD LIST) OUTPUT ITEM
  TO SQUISHED TEXT
  ELSE
    IF PREFERENCE IS SET TO PRESERVE PUNCTUATION
      SAVE PUNCTUATION TO MEMORY STORAGE
      SAVE PUNCTUATION PLACEMENT POSITION IN ITEM
      REMOVE PUNCTUATION FROM ITEM
      OUTPUT ITEM TO NEW PLAIN TEXT
    ELSE
      OUTPUT ITEM TO NEW PLAIN TEXT
```

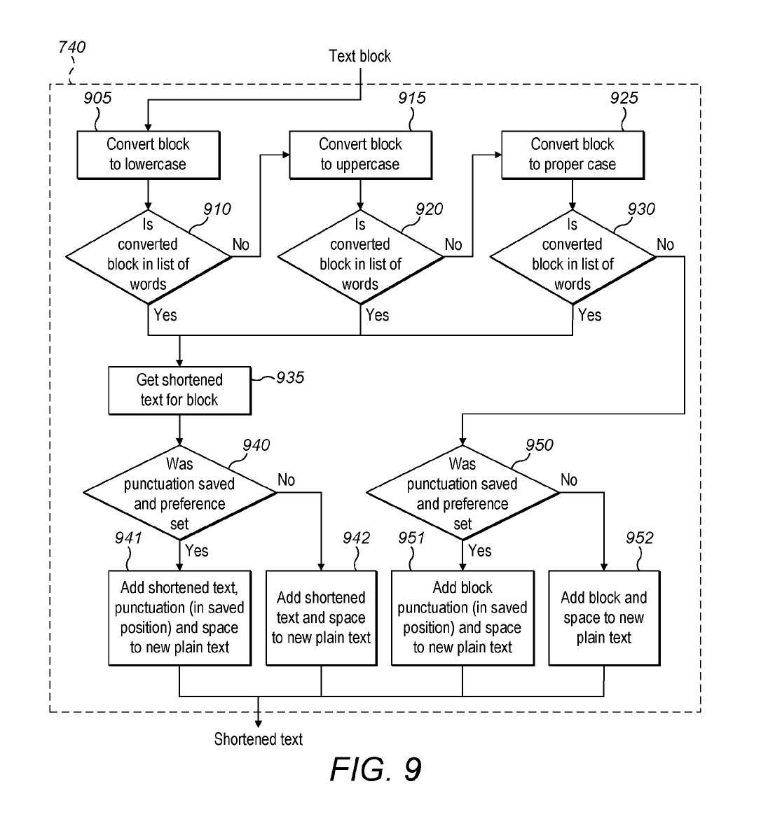

FIG. 9 illustrates the steps taken in the text shortening function 740 shown in FIG. 7. On receipt of a text block, the function first converts the block to lowercase 905. This lowercase text block is then checked 910 against the non-excluded data store for matches. If no matches are found, then the text block is converted to uppercase 915 and then the uppercase text is checked 920 to determine if it matches any entries in a non-excluded data store. If still no matches are found, the block is converted back to its original proper case 925 and then checked 930 to determine if there are any matches with the block in the non-excluded data store. If a match is found at any of steps 910, 920 and 930, then there will be an associated shortened version of the text block, which is subsequently fetched at step 935. Although the text may be converted to uppercase or lowercase for performing the comparisons, if a match is found, then the original case is applied to the text that replaces the word.

The ordering of steps 910, 920 and 930 is chosen to maximise the efficiency of the checks. If the main non-excluded data store contains mostly lowercase-only entries, then it would be most efficient to perform a lowercase entry search 910 first. However, if the non-excluded data store contains mostly uppercase-only entries, then the system would be modified so that steps 915 and 920 are performed before steps 905 and 910. If a system is used whereby the matching algorithm is not case sensitive, then no conversion to uppercase or lowercase would be required, and therefore steps 905 910, 915, 920 and 925 would not be required.

At step 940, the system determines whether any punctuation for the processed word had been saved during the punctuation processing function 715, and whether a preference had already been set to retain punctuation. If punctuation wasn't saved, or the preference was not set for retaining punctuation, then the shortened text is added to a new plain text with only a space 942. However, if punctuation was saved and a preference was set to preserve punctuation, then at step 941 the saved punctuation is added to the shortened text at the saved position, before a space is added as well and the result is output into the new plain text.

If no matches were found at steps 910, 920 and 930, then the original text block is sent to step 950 where a similar punctuation process to step 940 is performed. If it is determined that no punctuation was saved, or that no preference was set to preserve the punctuation, then the text block is moved to step 952 where the block is added with a space to an output plain text. If punctuation was saved for that block and the preference is retain punctuation was set, then at step 951 the saved punctuation is added to the saved position of the text block, a space is added and the result is output to the new plain text.

An example of pseudo code that can be used to express the functions of FIG. 9 is:

```
TRANSFORM ITEM TO LOWERCASE CHARCTERS
  IF ITEM IS IN LIST OR WORDS
    GET SHORTENED WORD TEXT
    IF PUNCTUATION WAS SAVED
    ADD SHORTENED WORD TEXT AND SAVED
    PUNCTUATION AND SPACE TO
    NEW PLAIN TEXT
    ELSE
    ADD SHORTENED WORD TEXT AND SPACE
    CHARACTER TO OUTPUT OF
    NEW PLAIN TEXT
  ELSE
  TRANSFORM ITEM TO UPPERCASE CHARCTERS
  IF ITEM IS IN LIST OR WORDS
    GET SHORTENED WORD TEXT
    IF PUNCTUATION WAS SAVED
    ADD SHORTENED WORD TEXT AND SAVED
    PUNCTUATION AND SPACE TO
    NEW PLAIN TEXT
    ELSE
    ADD SHORTENED TEXT AND SPACE TO OUTPUT OF
    NEW PLAIN TEXT
  ELSE
  TRANSFORM ITEM TO PROPER CASE CHARCTERS
  IF ITEM IS IN LIST OR WORDS
    GET SHORTENED WORD TEXT
    IF PUNCTUATION WAS SAVED
    ADD SHORTENED WORD TEXT AND SAVED
    PUNCTUATION AND SPACE TO
    OUTPUT OF NEW PLAIN TEXT
    ELSE
    ADD SHORTENED TEXT AND SPACE TO OUTPUT OF
    NEW PLAIN TEXT
ELSE
IF PUNCTUATION WAS SAVED
  AND ADD SHORTENED TEXT AND SAVED
  PUNCTUATION AND SPACE TO OUTPUT
  OF NEW PLAIN TEXT
ELSE
ADD ITEM AND SPACE TO OUTPUT OF NEW PLAIN TEXT
```

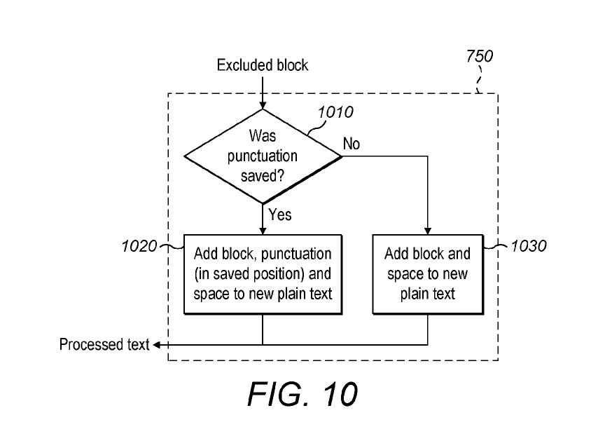

FIG. 10 illustrates the steps performed in the excluded text function 750. The steps performed are similar to those performed at steps 950, 951 and 952 of FIG. 9, but is performed on an excluded block which has not been checked for matches with shortened words. At step 1010, if punctuation is determined to have been saved (and optionally, if a preference was set to retain punctuation as well), then the excluded block has the saved punctuation added to the saved position 1020 and a space is added, before outputting the new plain text. If no punctuation was saved, however, then a space character is added to the excluded block and it is output as new plain text.

An example of pseudo code that can be used to express the functions of FIG. 10 is:

```
IF PUNCTUATION WAS SAVED
  (RESTORE PUNCTUATION TO ITEM)
  OUTPUT ITEM TO NEW PLAIN TEXT
```

Although pseudo code is used to express code examples in the present disclosure, it would be clear to a person skilled in the art that this code may be implemented in any coding language, for example Oracle JAVA, Microsoft C#.Net, C, Delphi, and Basic.

To illustrate the workings of the example embodiments described above, an example plain text input and its subsequent processing will be analysed. In this example, an SMS application has had the text “Sorry, can't wait, got to go!” input into the message field of the SMS application. The user may press a button to convert the text to shortened text, or it may even be shortened automatically on pressing the send button on the SMS application. In this example, the user sends instructs the device to shorten the message by pressing a button.

The plain text message is sent to step 341 of the text processing engine 340, which is already running as a background process, so steps 305 to 330 have already been initiated. In this example, the user has enabled the preference to process phrases and therefore a temporary data store is built for non-excluded phrases 405 as well as non-excluded words 410. The input text is then sent to the phrase processing function 430. The temporary data store for phrases contains a number of phrases, for example ‘as soon as possible’ (asap), ‘in my humble opinion’ (imho), and ‘got to go’ (g2g). At step 510, the system looks at the first entry in the temporary data store ‘as soon as possible’ and at step 520 determines if the input text contains this phrase. As it does not, it removes ‘as soon as possible’ from the temporary data store and returns to step 510. Here it checks for the next entry, ‘in my humble opinion’, and again returns to step 510 after a negative match. When the system reaches ‘got to go’ in the temporary data store at step 510 and performs the check at step 520, it does find the phrase in the input text “Sorry, can't wait, got to go!” and so proceeds to step 530. Here the system replaces ‘got to go’ in the input text to the mapped shortened word in the data store of ‘g2g’, resulting in “Sorry, can't wait, g2g!”. This modified text is sent back to step 510, and as there are no more unchecked entries in the temporary data store, this modified text is moved on to the words processing function 440.

Here, the text is split into blocks, based on the positioning of space characters. Therefore the input of “Sorry, can't wait, g2g!” is split into the blocks [Sorry,], [can't], [wait,] and [g2g!]. Each of these blocks are processed individually and preferably in order, unless the ordering is preserved in another way (for example, by assigning a position value to each block).

Each block has their punctuation processed at step 715. All four blocks contain punctuation so they all move on to step 810. In this example, the word “can't” is on a list of excluded abbreviated words, and therefore the block [can't] would pass straight 855 to the next stage of checking for exclusions 820. Blocks [Sorry,], [wait,] and [g2g!] are not on the abbreviated words list and so move on to step 815. In this example, the preference is set to preserve punctuation, so these three blocks move on to step 840. The punctuation for each block is saved and subsequently removed. Therefore, the system would save that a comma is at the end of blocks [Sorry,] and [wait,], and that an exclamation mark is at the end of [g2g!]. The modified blocks of [Sorry], [wait] and [g2g] would then be moved on to check for exclusions 820.

Each of the four blocks are then checked against exclusions at steps 721 to 732. In this example, only block [can't] is caught by the exclusion at step 729 and so is sent to step 750 where excluded blocks are processed. The remaining three blocks [Sorry], [wait] and [g2g] are moved on to the text shortening process 740.

In the text shortening process, each of the blocks are first converted to lowercase 905, so the blocks become [sorry], [wait] and [g2g]. They are then each compared 910 against the list of non-excluded words in the system's data store. In this example a match is found for [sorry] and [wait] and therefore these are sent to step 935. Block [g2g], however, does not have a match, so it is converted to uppercase 915 to [G2G] and checked 920, before being converted to the original case 925 [g2g] and checked again 930 and eventually sent to step 950. To avoid circumstances like this, blocks that have already had a conversion performed on them as a result of a phrase check may skip this checking process.

At step 935, the system retrieves the shortened versions it has stored for blocks [sorry] and [wait], which are [soz] and [w8] respectively. These modified blocks are then sent to step 940. As punctuation was saved, and the preference to preserve punctuation was enabled, these blocks move to step 941 where the punctuation is added to the saved position. Additionally, spaces are added, and original cases are returned at step 941, resulting in blocks [Soz,] and [w8,]. Similarly, the [g2g] block at step 950 is converted to [g2g!] at step 951.

Similar to steps 950, 951 and 952, the excluded word [can't] is processed at the excluded word function 750. As no punctuation was saved it moves to step 1030, where a space is added to form [can't].

Each of these blocks [Soz,], [can't], [w8,] and [g2g!] are then appended together and the final space character is removed, eventually forming “Soz, can't w8, g2g!” as the compressed output text of the system. This 19 character text is then returned to the original SMS application to replace the original 29 character text of “Sorry, can't wait, got to go!” The user may then decide that they do not want “can't” to be excluded, and may manually replace the word to “cnt”, resulting in a final text of “Soz, cnt w8, g2g!”. On making this correction, the user may indicate to the device that they wish for this correction to happen automatically in future, thus creating a user-define entry of “can't” to “cnt”.

As shown in the above example, the original plain text has been compressed into a form that is shorter, uses less memory, and still comprehensible to a reader of the text.

In an example embodiment, a real-time “predictive shortened text” could be provided, based on an input of the words predicted by the T9 system (using numeric keypads for alphabet entry) on mobile smartphone devices that would then suggest the predicted words shortened text equivalents. This could, for example, be placed on a ribbon-like interface above the existing T9 ribbon based interface of words on a smart device such as smart mobile phone or tablet pc.

In another example embodiment, voice dictated text could be instantly shortened with one execution of the proposed system, thus requiring no key presses by the user to dictate automatically shortened text.

In another example embodiment, the above described systems may be reversed so that on receiving shortened text, the system converts the shortened text to the traditional language equivalent. To accurately reverse-transform text to the original text, the receiving system would need the same entries as the system that initially transformed the text to shortened text. This may be achieved by having both systems access a remote data store containing the mapping and updating regularly.

In another example embodiment, after text has been converted to shortened text, the user is given an opportunity to manually edit the output text, and to indicate that they wish for certain conversions to be removed from future conversions.

Embodiments have been described herein by way of example and these embodiments are not intended to be limiting. Rather, it is contemplated that some embodiments may be subject to variation or modification without departing from the spirit and scope of the present disclosure. Furthermore, the individual algorithms used in the systems may be modified to improve the efficiency of the system and may vary depending on the scenario.

It is to be understood that the present disclosure includes all permutations of combinations of the optional features set out in the embodiments described above. In particular, it is to be understood that the features set out in the appended dependent claims are disclosed in combination with any other relevant independent claims that may be provided, and that this disclosure is not limited to only the combination of the features of those dependent claims with the independent claim from which they originally depend.

1-14. (canceled)

15. A computer program on an electronic device for processing text, the computer program running as a background service in communication with a plurality of communication applications on the electronic device, and performing the method of:
receiving plain text from one of the plurality of software applications;
processing the text into compressed text, while maintaining comprehensibility of the compressed text; and
returning the compressed text to the one of the plurality of software applications.

16. The computer program of claim 15, wherein the compressed text is text speak.

17. The computer program of claim 15, wherein the step of processing the text into compressed text includes accessing a dictionary comprising one or more mappings of groups of text characters to compressed text.

18. The computer program of claim 17, wherein the dictionary is stored locally on the electronic device.

19. The computer program of claim 18, wherein the dictionary further comprises custom mappings added by the electronic device.

20. The computer program of claim 15, wherein the processing the text into compressed text is ceased when the compressed text falls below a predetermined size.

21. The computer program of claim 20, wherein the predetermined size is the string length.

22. The computer program of claim 17, wherein the processing of text comprises:
splitting the received text into blocks of text, said splitting determined by the positions of space characters in the received text; and
for each block of text, if it the block of text is determined to have a mapping in the dictionary, replacing it with the corresponding compressed text.

23. The computer program of claim 22, wherein the processing of text further comprises:
for each block of text, if the block of text is determined to be an excluded block of text, skipping the step of determining if the block of text has a mapping in the dictionary.

24. The computer program of claim 15, wherein the compressed text uses less memory than the received text.

25. The computer program of claim 15, the method further comprising:
detecting that the received text is compressed text and processing the text into uncompressed text.

26. The computer program of claim 15, wherein the plurality of communication applications include one or more of: a text messaging application, a Twitter® application, an email application, and a social networking application.

27. An electronic device comprising:
one or more processors; and,
memory comprising instructions which, when executed by one or more of the processors, cause the device to run a background service in communication with a plurality of communication applications on the electronic device, and to:
receive plain text from one of the plurality of software applications;
process the text into compressed text, while maintaining comprehensibility of the compressed text; and
return the compressed text to the one of the plurality of software applications.

28. The electronic device of claim 27, wherein the compressed text is text speak.

29. The electronic device of claim 27, wherein the step of processing the text into compressed text includes accessing a dictionary comprising one or more mappings of groups of text characters to compressed text.

30. The electronic device of claim 29, wherein the dictionary is stored locally on the electronic device.

31. The electronic device of claim 30, wherein the dictionary further comprises custom mappings added by the electronic device.

32. The electronic device of claim 27, wherein the processing the text into compressed text is ceased when the compressed text falls below a predetermined size.

33. The electronic device of claim 32, wherein the predetermined size is the string length.

34. The electronic device of claim 29, wherein the processing of text comprises:
splitting the received text into blocks of text, said splitting determined by the positions of space characters in the received text; and
for each block of text, if it the block of text is determined to have a mapping in the dictionary, replacing it with the corresponding compressed text.

35. The electronic device of claim 34, wherein the processing of text further comprises:
for each block of text, if the block of text is determined to be an excluded block of text, skipping the step of determining if the block of text has a mapping in the dictionary.

36. The electronic device of claim 27, wherein the compressed text uses less memory than the received text.

37. The electronic device of claim 27, the method further comprising:
detecting that the received text is compressed text and processing the text into uncompressed text.

38. The electronic device of claim 27, wherein the plurality of communication applications include one or more of: a text messaging application, a Twitter® application, an email application, and a social networking application.

39. A non-transitory computer-readable medium comprising instructions which, when executed by one or more processors of an electronic device, cause the device to run a background service in communication with a plurality of communication applications on the electronic device, and to:
receive plain text from one of the plurality of software applications;
process the text into compressed text, while maintaining comprehensibility of the compressed text; and
return the compressed text to the one of the plurality of software applications.
